(19) United States
(12) Patent Application Publication
(10) Pub. No.: US 2024/0047258 A1
(43) Pub. Date: Feb. 8, 2024

(54) PLASMA PROCESSING APPARATUS

(71) Applicant: Hitachi High-Tech Corporation, Minato-ku, Tokyo (JP)

(72) Inventors: Tomoyuki Tamura, Tokyo (JP); Kazuyuki Ikenaga, Tokyo (JP)

(21) Appl. No.: 17/642,821

(22) PCT Filed: Feb. 25, 2021
(86) PCT No.: PCT/JP2021/007005

§ 371 Date: Mar. 14, 2022

(51) Int. Cl. H01L 21/683; H01L 21/687; H01J 37/32; H01L 21/67

(52) U.S. Cl. CPC H01L 21/6833; H01L 21/68742; H01J 37/32477; H01L 21/67063

(57) ABSTRACT

A plasma processing apparatus including a processing chamber; a wafer stage on which a processing target wafer is placed; an electrostatic chuck including a film-shaped electrostatic attraction electrode which is disposed in a dielectric film covering an upper surface of the wafer stage; a radio frequency electrode which is disposed inside the wafer stage; and a lift pin which is disposed inside the wafer stage and which moves the wafer up and down by movement thereof, a lower portion of the lift pin being connected to a member made of a conductor, in which a voltage value Eps of the lower portion of the lift pin and an average value Eesc of the potential of the electrostatic attraction electrode are adjusted during the processing of the wafer so as to match the predicted value Vdcs of the self-bias voltage of the wafer.

### TECHNICAL FIELD

The present invention relates to a plasma processing apparatus that processes a substrate-shaped sample such as a semiconductor wafer disposed in a processing chamber in a vacuum container by using plasma generated in the processing chamber, which is a semiconductor wafer processing apparatus used in a process of manufacturing a semiconductor device, and particularly relates to a plasma processing apparatus including: a wafer stage (placement electrode) which is disposed in a processing chamber and on an upper surface of which a sample such as a semiconductor wafer is placed; and a plurality of push-up pins (lift pins, lifting pins) for the sample that each move in an up and down direction between a position where the push-up pin is stored inside a hole disposed in the wafer stage, and a position where the push-up pin protrudes upward from an opening of the hole in the upper surface of the wafer stage so as to make the wafer placed on a tip of the push-up pin.

### BACKGROUND ART

Inside a processing chamber disposed inside a plasma processing apparatus as described above, a substrate such as a semiconductor wafer that is a processing target sample is held in a state of being placed on an upper surface of a wafer stage (placement electrode) and is exposed to plasma generated by using gas supplied into the processing chamber, and radio frequency power is supplied to an electrode disposed in the wafer stage in a state where a surface of the wafer on which a processing target film layer is formed in advance is in contact with charged particulates such as ions or neutral reactive particulates such as active species in the plasma. Therefore, the film layer on the surface of the wafer is subjected to etching processing or the like by interaction with the above particulates. By the radio frequency power supplied to the electrode, a radio frequency potential is formed on the wafer held on the wafer stage, but the potential has an offset toward a negative side by a predetermined value with respect to an electrostatic potential of the plasma. A value of a direct current component of the potential that has the offset toward the negative side is called a self-bias.

A potential difference is generated between the wafer on which the potential having a self-bias value is formed by the radio frequency power and a conductive member of a component in the processing chamber disposed around the wafer, and when the potential difference is larger than a certain value, problems arise that a circuit of an element including a pattern formed on the wafer by processing using the plasma is destroyed due to occurrence of discharge and a yield of processing is impaired. As a technique for preventing the problems, a technique described in WO2003/009363 (PTL 1) has been known in the related art. In the related art, a technique is disclosed in which, in order to prevent discharge between a focus ring disposed around a wafer on a wafer stage and the wafer, a potential of the focus ring is controlled so as to match a potential of the wafer, or a height of a lift pin on a back surface of the wafer is finely adjusted so as to control a gap between the wafer and an upper end of the lift pin and to prevent discharge in the gap. Further, JP-T-2001-506808 (PTL 2) describes a technique for preventing element destruction by moderating, by electrical resistance, a current when electric charges remaining on a substrate flow from a conductive member of a lifting pin through a substrate lifting device to an earth, the lifting pin moving upward to be in contact with the substrate at a tip of the lifting pin in order to lift the substrate (wafer) after completion of plasma processing, and the substrate lifting device driving the lifting pin connected to the earth via an electrical connection portion. Further, JP-A-2011-187881 (PTL 3) describes a technique in which an offset amount of a potential between attraction electrodes of both positive and negative electrodes is adjusted during plasma etching based on a leak current flowing from each of the electrodes through plasma according to a self-bias of a wafer in an electrostatic attraction apparatus including a so-called dipole electrostatic chuck in which different polarities are imparted to the plurality of electrodes which electrostatically attract the wafer. Further, JP-T-2002-507326 (PTL 4) describes a technique for detecting a difference between currents flowing through two electrodes (buried plates) of an electrostatic chuck in a state where a wafer is charged during plasma etching, and adjusting a voltage to be applied to each of these electrodes.

### CITATION LIST

### Patent Literature

PTL 1: WO2003/009363
PTL 2: JP-T-2001-506808
PTL 3: JP-A-2011-187881
PTL 4: JP-T-2002-507326

### SUMMARY OF INVENTION

### Technical Problem

However, in the related art described above, problems arise because the following points are not taken sufficiently into consideration.

That is, a plasma processing apparatus in the related art has a configuration in which a lift pin is stored and disposed inside a hole disposed in advance in a wafer stage, a lower portion of the lift pin is connected to a support tool (also referred to as a support member) connected to a drive device including a motor, an actuator, or the like disposed in a space provided under or below the wafer stage, and the support member moves in the space in an up and down direction due to an operation of the drive device, and whereby a tip portion of the lift pin can move between a position where the tip portion is stored inside the hole and a position where the tip portion supports a wafer above an upper surface of the wafer stage. The hole in which such a lift pin is stored is formed by penetrating a coating made of a dielectric material, which is disposed to cover a base member of the wafer stage made of a metal and having a cylindrical shape or a disk shape and an upper surface thereof, and in which an electrostatic attraction electrode is incorporated, or by further penetrating a disk member made of an insulating material which is connected to a bottom surface of the base member of the wafer stage, and the above space is disposed below the base member of such a wafer stage.

Further, in the plasma processing apparatus in which an inner wall of a processing chamber, which is configured with a metallic member and inside which plasma is generated, is covered with an insulating material (dielectric), and the lift pin is made of a dielectric material, a component may be located below the lift pin, whose support member is configured with a metallic member, and a surface of the component configured with a conductive member may be exposed in the space below the base member. In such a case, problems arise that during processing or the like in which a semiconductor wafer is etched by forming the plasma inside the processing chamber and supplying radio frequency power to the metal base member or an electrode inside the dielectric film, power leakage occurs between the conductive member and the wafer, a potential of a self-bias of the wafer is a value different from a value obtained as a result of desired processing, and a yield of the processing is impaired.

In the related art described above, problems that the potential of the wafer is not appropriate and particles are further generated are not taken into consideration.

An object of the invention is to provide a plasma processing apparatus which stabilizes a potential of a wafer that is being processed and improves a yield of processing.

### Solution to Problem

The above object is achieved by a plasma processing apparatus including: a processing chamber which is disposed inside a vacuum container and inside which plasma is to be generated; a wafer stage which is disposed inside the processing chamber and on which a processing target wafer is placed; an electrostatic chuck including a film-shaped electrostatic attraction electrode which is disposed in a dielectric film covering an upper surface of the wafer stage and which electrostatically attracts the wafer placed on the dielectric film; a radio frequency electrode which is disposed inside the wafer stage and to which radio frequency power is supplied during processing of the wafer; and a lift pin which is disposed inside the wafer stage and which moves the wafer up and down by movement thereof in an up and down direction, a lower portion of the lift pin being connected to a member made of a conductor, in which when an electrical resistance value between the electrostatic attraction electrode and the wafer is set as Resc, an electrical resistance between the plasma and a ground electrode with an inner wall surface of the processing chamber interposed between the plasma and the ground electrode is set as Rc, a withstand voltage between the plasma and the vacuum container constituting the processing chamber is set as Vt, and a predicted maximum value of a difference between a self-bias voltage Vdc actually generated in the wafer during the processing of the wafer and a predicted value Vdcs thereof is set as δ max, a resistance value Rps between a direct current power source and the lower portion of the lift pin electrically connected to the direct current power source is set to a range of 100 MΩ>Rps>1/{(Vt/((δ max−Vt)×Rc))−(1/Resc)}, and when an average value of a potential of the electrostatic attraction electrode is set as Eesc, a voltage value Eps of the lower portion of the lift pin and the average value Eesc of the potential of the electrostatic attraction electrode are adjusted during the processing of the wafer so as to match the predicted value Vdcs of the self-bias voltage of the wafer.

### Advantageous Effect

According to the invention, an increase in an average potential of a wafer can be prevented even if sudden conduction occurs in a lift pin portion during plasma etching. As a result, an increase in an average potential of plasma can be prevented, a potential difference applied to a dielectric film between the plasma and an earth or a metal base member of a housing can be reduced, abnormal discharge caused by dielectric breakdown or the like of the dielectric film on an inner wall of a processing chamber can be prevented, and generation of particles can be prevented.

### BRIEF DESCRIPTION OF DRAWINGS

FIG. 1 is a longitudinal sectional view schematically showing an outline of a configuration of a plasma processing apparatus according to an embodiment of the invention.

FIG. 2 is a longitudinal sectional view schematically showing an outline of a configuration obtained by adding an equivalent circuit including plasma generated during processing of a wafer, and an element thereof, to the configuration of the plasma processing apparatus according to the embodiment shown in FIG. 1.

FIG. 3 is a longitudinal sectional view schematically showing an example of a method for detecting an electrical resistance Rc and a withstand voltage Vt of an inner wall of a processing chamber in the plasma processing apparatus according to the embodiment shown in FIG. 1.

FIG. 4 is a graph showing a change in a resistance value obtained by using the detecting method shown in FIG. 3 with respect to a change in a voltage applied from a variable direct current power source to a temporary electrode.

FIGS. 5A and 5B are graphs schematically illustrating an appropriate range of a resistance value of a lower portion of a lift pin of the invention.

FIGS. 6A and 6B are graphs showing a change in output from a power source associated with a change in time during processing of the wafer performed by the plasma processing apparatus according to the embodiment shown in FIG. 1.

FIG. 7 is a graph in which a lower limit value of a required lift pin lower portion resistance Rps is obtained.

### DESCRIPTION OF EMBODIMENTS

In a plasma processing apparatus in the related art, when a metallic lift pin support tool which is provided with a mechanism, that moves a lift pin in an up and down direction, at a lower portion of the lift pin, and which is connected to the lower portion of the lift pin to support the lift pin from below is used, and a metallic bellows is used at a location around an opening of a lift pin hole, inside which the lift pin is stored, to vacuum seal the lift pin hole between an inside of a processing chamber and a space below a base member which are in communication with the lift pin hole, in order to maintain the space below the base member in which the mechanism is disposed at pressure (for example, pressure equivalent to atmospheric pressure or ambient pressure) higher than that in the processing chamber, sufficient insulation may not be realized between these metallic members and a radio frequency electrode in a wafer stage to which radio frequency power is supplied, or between these metallic members and a wafer.

Further, also in the related art, when a dielectric such as alumina, which is less prone to wear, is used as a material of the lift pin, the wafer and a member made of a conductive material are spaced apart from each other by a predetermined distance, for example, 5 cm or more, and are galvanically insulated from each other. Therefore, an inner wall of the lift pin hole is made of a dielectric material, and is designed such that discharge does not occur even in a state where the radio frequency power is supplied. However, when the radio frequency power applied to the electrode in the wafer stage and radio frequency power for generating plasma increase, dielectric barrier discharge is sporadically generated in a space inside the lift pin hole, the wafer and a component configured with a conductive member below the lift pin are electrically connected with each other, that is, the radio frequency power leaks from the wafer to the conductive member below the lift pin, and an absolute value of an average potential of the wafer is reduced. That is, the inventors have found that a potential of the conductive member below the lift pin may affect the average potential of the wafer.

The inventors conceive of the invention in order to solve such a problem, and an embodiment of the invention has the following configuration in order to solve the above problem.

A plasma processing apparatus according to the present embodiment includes a processing chamber which is disposed inside a vacuum container and inside which plasma is to be generated, the processing chamber has a cylindrical shape that surrounds a space in which the plasma is generated at a part of the processing chamber, and an inner wall of the processing chamber is covered with a dielectric cover having a predetermined thickness. In addition, a metallic radio frequency electrode in a wafer stage is mainly connected to a first radio frequency power source used to attract charged particulates in the plasma to a surface of a wafer by forming a bias potential during processing, and is supplied with first radio frequency power. The plasma processing apparatus further includes a second radio frequency power source that supplies second radio frequency power for generating the plasma inside the processing chamber.

At least a part of each of a plurality of lift pins that lift and separate the wafer above an upper surface of the wafer stage is made of a dielectric material, and a lower end portion of the lift pin is connected to a lift pin support tool disposed in a space below a lift pin hole penetrating a base member of the wafer stage and is supported from below. The lift pin support tool has a portion (component) that is configured with a conductive member such as a metal and faces an inside of a space below the base member.

In the present embodiment, the portion (component) is connected to a variable direct current power source via an electrical resistance (hereinafter, referred to as a lift pin lower portion resistance Rps) having a predetermined value, and an output of the variable direct current power source is adjusted such that a potential of the portion (component) is a predetermined lift pin lower portion voltage Eps. Further, a bipolar (dipole) electrostatic chuck in which different polarities are imparted to film-shaped electrodes is disposed, the film-shaped electrodes are disposed inside a dielectric film, which is disposed on the upper surface of the wafer stage, and attract a plurality of wafers.

Further, when values of a plasma-earth withstand voltage Vt and a plasma-earth direct current electrical resistance Rc of the dielectric cover constituting an inner wall surface of the processing chamber, are acquired in advance before processing of a processing target wafer is started, and an electrical resistance between the electrodes of the electrostatic chuck and the wafer is set as an electrostatic chuck resistance Resc, the lift pin lower portion resistance Rps is adjusted so as to be within a range represented by the following formula.

100 MΩ>Rps>1/{(Vt/((δ max−Vt)×Rc))−(1/Resc)}

Further, while the second radio frequency power is supplied from the second radio frequency power source to generate the plasma and the first radio frequency power is supplied from the first radio frequency power source to the wafer stage to perform processing of a processing target film layer on the wafer, both an average voltage (an electrostatic chuck average voltage) Eesc of both electrodes for the electrostatic chuck and the lift pin lower portion voltage Eps are adjusted to be an estimated value Vdcs of a self-bias potential of the wafer.

Here, δ max indicates a maximum value of an estimated potential difference δ during the processing of the wafer when the lift pin lower portion voltage Eps and the electrostatic chuck average voltage Eesc may be different from an actual self-bias potential Vdc of the wafer. The maximum value δ max of the potential difference includes a deviation in voltage resulting from adjustment accuracy of the lift pin lower portion voltage Eps or the electrostatic chuck average voltage Eesc.

Further, in an example described below, the estimated value Vdcs of the self-bias potential of the wafer that is being processed is expressed as a function of a value Vpp of a width (amplitude) of maximum value-minimum value of a voltage of the first radio frequency power (radio frequency voltage) so as to approximately match the self-bias potential Vdc obtained by an experiment or the like performed in advance, and the first radio frequency power is supplied to the base member which is a metallic electrode of the wafer stage. Further, a difference between the actual self-bias potential Vdc and the estimated value Vdcs of the self-bias potential under a plurality of processing conditions for the wafer is set as a potential difference δ. Then, a sum of a maximum potential difference among the potential differences δ obtained in the processing of the wafer performed under the plurality of processing conditions by using the plasma processing apparatus according to the present embodiment and an error caused by control accuracy is set as the maximum value δ max of the potential difference.

Alternatively, in another example, when a width of maximum value-minimum value of a radio frequency potential (an amplitude of the radio frequency potential) generated on the wafer by supplying the first radio frequency power from the first radio frequency power source is set as Vppw, and a maximum Vppw used in the processing of the wafer performed under the plurality of processing conditions by using the plasma processing apparatus according to the present embodiment is set as Vppwmax, values of the estimated value Vdcs of the self-bias potential and the maximum value δ max of the potential difference δ are obtained by the following formulas.

Vdcs=−0.27×Vppw

δ max=0.17×Vppwmax+error caused by control accuracy

Vppw can be calculated, for example, by omitting a harmonic and assuming a fundamental wave, based on a match value of a width (amplitude) Vpp of maximum value-minimum value of the first radio frequency voltage and a matching box, and an impedance Z from a location on a power feeding path, where Vpp is detected, to the wafer, and the width is detected at an outlet of the matching box disposed on the power feeding path of the first radio frequency power that electrically connects the first radio frequency power source and the base member of the wafer stage.

Hereinafter, an embodiment will be described with reference to drawings.

### First Embodiment

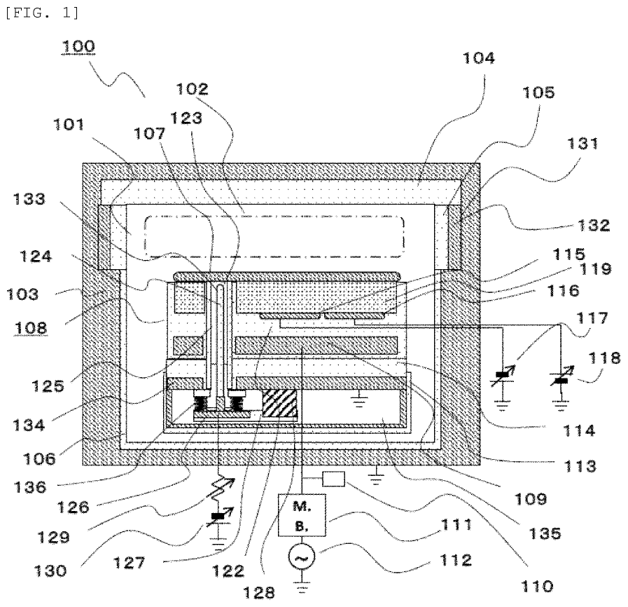

Hereinafter, an embodiment of the invention will be described with reference to FIGS. 1 to 5B.

FIG. 1 is a longitudinal sectional view schematically showing an outline of a configuration of a plasma processing apparatus according to the embodiment of the invention. A plasma processing apparatus 100 of the present embodiment is an etching processing apparatus that processes, using plasma generated in a processing chamber, a processing target film layer having a film structure in which a plurality of film layers are stacked in an up and down direction. The plurality of film layers include a mask layer and the processing target film layer which are formed in advance on a surface of a substrate-shaped sample such as a semiconductor wafer. The substrate-shaped sample is a processing target disposed in a space inside a vacuum container.

The plasma processing apparatus 100 of the present example includes: a processing chamber 101 inside which a wafer 107 is disposed and processed with generated plasma; an exhaust mechanism which is connected to a bottom of the vacuum container so as to communicate with the processing chamber 101 and is sequentially connected, via a pipe or a duct, with an exhaust amount adjusting mechanism (not shown) such as a valve and a vacuum pump (not shown); and a gas supply line (not shown) which is connected to an upper portion of the vacuum container and includes a gas introduction pipe through which processing gas necessary for generating the plasma for subjecting the wafer 107 to etching processing is introduced and a flow rate adjuster for the processing gas. In the plasma processing apparatus of the present example, pressure in the processing chamber 101 is maintained at a pressure value within a predetermined range suitable for the processing of the wafer 107 and an operation process of the plasma processing apparatus 100 due to a balance between a flow rate or speed at which the processing gas or dilution gas from the gas supply line is introduced into the processing chamber 101, and a flow rate or speed of exhaust gas exhausted by an operation of the exhaust mechanism which communicates with an exhaust port disposed at a bottom of the processing chamber 101.

Further, a microwave generator (not shown) such as a magnetron and a solenoid coil are provided at the upper portion of the vacuum container. The microwave generator generates, inside the processing chamber 101, an electric field for generating the plasma, by second radio frequency power of a predetermined frequency (microwave band in the present example) from a second radio frequency power source. The solenoid coil generates, in the processing chamber 101, a magnetic field having a distribution and an intensity appropriately adapted to the electric field of microwaves. The processing gas supplied to the processing chamber 101 is excited by the electric field or the magnetic field supplied from these components, and then ionization and dissociation occur to generate plasma 102.

The processing chamber 101 in the present embodiment is surrounded by a metallic housing 103 constituting the vacuum container, and an inner wall surface of the processing chamber 101 is covered with a cover made of a dielectric material such that the inner wall surface of the housing 103 is not directly in contact with the plasma in order to prevent occurrence of contamination inside the processing chamber 101 due to interaction between the inner wall surface of the processing chamber 101 and the plasma 102. The dielectric cover in the present example includes: a disk-shaped top plate 104 which is made of quartz and constituting a top surface of the processing chamber 101; a thermally sprayed film 105 which is disposed to cover an inner peripheral wall surface of a ring-shaped metallic earth electrode 131 surrounding an upper portion of the processing chamber 101 and is coated by a thermal spraying method using a ceramic material such as alumina or yttria; and an anodized film 106 which is formed on a surface of a base material made of aluminum or an alloy thereof.

A placement electrode 108 serving as the wafer stage, on an upper surface of which the wafer 107 is placed, is disposed at a lower portion of a space inside the processing chamber 101. As described above, the placement electrode 108 is provided therein with a base member 109 made of a metal, which is connected to a radio frequency power source 112 that is a first radio frequency power source, and has a disk shape or a cylindrical shape. The base member 109 is electrically connected, via a matching box 111, to the radio frequency power source 112 that is the first radio frequency power source, and the first radio frequency power source outputs first radio frequency power of 400 kHz which forms a bias potential on the wafer 107 in order to attract charged particulates such as ions in the plasma 102 to an upper surface of the wafer 107 during the processing of the wafer 107. Further, a detector 110, which monitors a width (amplitude) Vpp of maximum value−minimum value of a first radio frequency voltage from the radio frequency power source 112, is disposed at a location on a power feeding path of the first radio frequency power and between the matching box 111 and the base member 109. Further, a film 113 made of a dielectric is disposed around and covers the placement electrode 108, and an insulating plate 114 made of a dielectric (insulating material) is disposed below the base member 109.

An upper surface of the placement electrode 108 is formed in a substantially circular shape according to a shape of the wafer 107. The upper surface of the placement electrode 108 is covered with a film (dielectric film) 122 made of a dielectric such as alumina or yttria, and an inner electrostatic chuck electrode 115 and an outer electrostatic chuck electrode 116 are disposed inside the film 122 and serve as film-shaped electrodes that electrostatically attract the wafer 107 placed on the placement electrode 108. The inner electrostatic chuck electrode 115 and the outer electrostatic chuck electrode 116 are electrically connected to variable direct current power sources 117 and 118 via low-pass filters (not shown), respectively. The wafer 107 is attracted and held on the dielectric film 122 by an electrostatic force formed across an upper surface of the dielectric film 122 according to voltages formed on films of these electrodes by supplying direct current power.

A plurality of electrodes, which include the inner electrostatic chuck electrode 115 and the outer electrostatic chuck electrode 116 which are disposed inside the dielectric film 122 constituting the upper surface of the placement electrode 108 in the present embodiment, constitute a so-called bipolar (dipole) electrostatic chuck to which power is supplied from the variable direct current power sources 117 and 118 so as to impart different polarities to the electrodes. In the present example, an average voltage between positive and negative electrodes of these bipolar electrostatic attraction electrodes is set as Eesc. The electrostatic chuck is a J-R electrostatic chuck that attracts the wafer 107 by a Johnsen-Rahbek (J-R) effect.

Inside the placement electrode 108, through holes 123, which penetrate the base member 109 and the dielectric film 122 disposed thereon, are disposed at three or more locations (there are three locations in the present example but only one location is shown). A lift pin 124 made of a dielectric material is disposed inside each of the through holes 123, and is driven so as to move up and down along an axis in an up and down direction of the through hole 123 between a position where the lift pin 124 including a tip is stored inside the through hole 123 and a position where the tip is located at a predetermined height above the upper surface of the dielectric film 122. By moving the lift pin 124 up and down, the wafer 107 placed and supported on the tip of each pin is transferred between a state where the wafer 107 is separated upward from the upper surface of the placement electrode 108 and a state where the wafer 107 is placed on the upper surface of the dielectric film 122.

Inside the through hole 123, a cylindrical boss 125 made of an insulating material (dielectric) is inserted into the through hole 123, and the through hole 123 is covered with a member made of a dielectric from an upper end thereof to a lower end thereof. A gap exists between an inner wall surface of the boss 125 and the lift pin 124 such that the lift pin 124 is not in contact with the inner wall surface during an operation in the up and down direction. The through hole 123 penetrates the dielectric film 122, the base member 109, the insulating plate 114 having a disk shape disposed below the base member 109, and a base plate 134 electrically connected to a ground electrode. The dielectric film 122, the base member 109, the insulating plate 114, and the base plate 134 constitute the placement electrode 108. The boss 125 extends from an upper surface of the base member 109 to a lower surface of the base plate 134.

A space 135 below the base plate 134 is a space contained in the placement electrode 108 and is provided inside with a beam portion 127 having a lift pin holder 126, and the lift pin holder 126 is made of a conductive material such as a metal, which is connected to a lower end portion of the lift pin 124 and supports the lift pin 124. At the beam portion 127 disposed in the space 135, the lower end portion of the lift pin 124 is connected to an upper surface of a tip portion of the lift pin holder 126 at a position where an electric field of a radio frequency potential of the wafer placement electrode 108 in the space 135 is weakened, and a base portion of the beam portion 127 is connected to a drive mechanism 128 disposed in a central portion of the space 135. The drive mechanism 128 is configured to expand and contract in the up and down direction in the drawing, and due to the operation, the lift pin holder 126 moves in the space 135 in the up and down direction together with the beam portion 127, and whereby the lift pin 124 moves between the position where the lift pin 124 is stored inside the through hole 123 and the position where the lift pin 124 protrudes above the dielectric film 122.

Further, the beam portion 127 extends radially from the base portion located in the central portion of the space 135 toward an outer peripheral side, and the lower end portion of the lift pin 124 is connected to the upper surface of the tip portion of the lift pin holder 126 made of the conductive material such as the metal. Further, a bellows (bellows structure) 136 is provided between the upper surface of the lift pin holder 126 centered on the lower end portion of the lift pin 124 and a bottom surface of the base plate 134 above the lift pin holder 126, and the bottom surface is a surface around an opening at the lower end of the through hole 123. The bellows 136 surrounds and covers the lift pin 124 and the opening at the lower end of the through hole 123 so as to hermetically partition an inner region below the through hole 123 from a part of the outer space 135, and can expand and contract in response to the up and down movement of the lift pin holder 126.

An inside of the bellows 136 in the present embodiment communicates with the inside of the processing chamber 101 via the through hole 123, and a metallic member of the surface of the tip portion of the lift pin holder 126 inside the bellows 136 is substantially exposed inside the through hole 123 or in the processing chamber 101. The metallic member, which is exposed inside the bellows 136 and constitutes the surface of the tip portion of the lift pin holder 126, is electrically connected to a variable direct current power source 130 via a lift pin lower portion resistance Rps 129, and power supplied from the variable direct current power source 130 is adjusted such that a potential of the metallic member is a predetermined lift pin lower portion voltage Eps.

During the processing of the wafer 107, while the radio frequency power from the first radio frequency power source 112 is being supplied to the wafer 107 through the base member 109, it is necessary to prevent a potential of the plasma 102 from being affected and changed by a potential formed on the wafer 107 due to the radio frequency power. Accordingly, in the present embodiment, in order to earth the plasma 102 at a radio frequency, the earth electrode 131 is disposed inside the processing chamber 101, and the earth electrode 131 includes the thermally sprayed film 105 that is disposed at a location surrounding a space in which the plasma 102 is generated in the upper portion of the processing chamber 101 as described above, that covers the inner peripheral wall surface of the earth electrode 131 facing the plasma 102, and that is formed by coating the inner peripheral wall surface with the ceramic material such as alumina or yttria at a thickness of several micrometers to several hundred micrometers by the thermal spraying method. Further, a surface area of the earth electrode 131 facing the plasma 102 is larger than a bottom area of the wafer 107.

In the present embodiment, the thermally sprayed film 105, which is formed by thermally spraying a material containing yttria having higher plasma resistance as a main component, is disposed on an inner peripheral surface of the earth electrode 131 facing the plasma, and the earth electrode 131 has a ring shape to surround an upper region where a density of the plasma 102 generated inside the processing chamber 101 is high. On the other hand, the anodized film (anodized coating) 106, which is formed on the surface made of aluminum that is the base material by anodization processing, is disposed on an inner wall surface of the processing chamber 101 in the housing 103 below the earth electrode 131. Except for the wafer 107, the inner wall surface of the processing chamber 101 surrounding the plasma 102 and a periphery of the wafer placement electrode 108 are covered with a dielectric together with a surface of the top plate 104 which is made of quartz and disposed above the processing chamber 101 so as to cover the processing chamber 101.

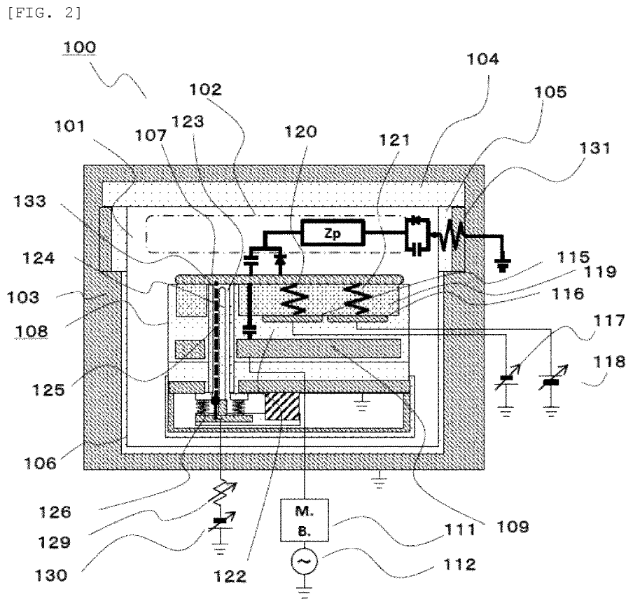

In the present embodiment, as described above, a value of the lift pin lower portion resistance 129 between the lift pin 124 and the variable direct current power source 130 is adjusted to a range determined by a relationship in which values of a resistance value Rc and a withstand voltage Vt between the ground electrode and a member constituting the inner wall surface of the processing chamber 101 are used as parameters. Therefore, the withstand voltage Vt and the resistance value Rc of an inner wall of the processing chamber 101 in the present embodiment will be described below with reference to FIGS. 1 and 2.

FIG. 2 is a longitudinal sectional view schematically showing an outline of a configuration obtained by adding an equivalent circuit including the plasma generated during the processing of the wafer, and an element thereof, to the configuration of the plasma processing apparatus according to the embodiment shown in FIG. 1.

As shown in FIGS. 1 and 2, the housing 103 constituting the vacuum container surrounding the processing chamber 101 in the present embodiment is formed by several portions, and is electrically connected to the ground electrode (not shown) to have a ground potential (earth potential). In the present embodiment, the electrical resistance value Rc of the inner wall of the processing chamber 101 is regarded as an electrical resistance value of a direct current flowing from the entire inner wall surface of the processing chamber 101 in contact with the plasma 102 to the ground electrode through the housing 103, and an electrical resistance value when a voltage corresponding to the withstand voltage Vt (or a voltage value equal to or slightly smaller than the withstand voltage) is applied between the plasma 102 and the housing 103 is set as Rc. In FIG. 2 and FIGS. 3 to 5B, Rc is shown as an electrical resistance 132, which is one element of the equivalent circuit when a direct current voltage is regarded as being applied between the entire inner wall surface of the processing chamber 101, that is in contact with the plasma 102, and the ground electrode through the housing 103.

Further, in the present embodiment, magnitudes (performances) of withstand voltages of members between the ground electrode and the plasma 102 including respective portions of the housing 103 are not the same in a state where the plasma 102 is generated inside the processing chamber 101, and for example, a portion having a low withstand voltage, such as a corner portion of the housing 103 or a thin portion of the dielectric film constituting the cover, is present. In the present embodiment, a value of a withstand voltage of a portion having the lowest withstand voltage between the plasma 102 and the respective portions of the housing 103 is set as the withstand voltage Vt of the inner wall of the processing chamber 101.

In addition, in the state where the wafer 107 is placed on the upper surface of the dielectric film 122 of the placement electrode 108, the plasma 102 is generated inside the processing chamber 101, and the first radio frequency power is supplied from the first radio frequency source 112 to the base member 109 to form the bias potential on the upper surface of the wafer 107. Further, the dielectric film 122, and the inner electrostatic chuck electrode 115 and the outer electrostatic chuck electrode 116 which are disposed inside the dielectric film 122 are provided, and currents flow between these electrodes and the wafer 107 according to direct current power supplied to the inner electrostatic chuck electrode 115 and the outer electrostatic chuck electrode 116. These currents are currents required to obtain a force for attracting the wafer 107, and flow respectively between the inner electrostatic chuck electrode 115 and the wafer 107, and between the outer electrostatic chuck electrode 116 and the wafer 107, passing through electrical resistances, which have values 120 and 121 respectively, of a semi-conductive film 119 constituting the dielectric film 122.

Further, electrostatic capacitances corresponding to materials and shapes of the semi-conductive film 119 and the dielectric film 122 are also present between these electrodes and the wafer 107 according to the direct current power supplied to the inner electrostatic chuck electrode 115 and the outer electrostatic chuck electrode 116. The first radio frequency power supplied to the base member 109 is coupled to the plasma 102 through an electrostatic capacitance of the dielectric film 122 including the semi-conductive film 119 and an electrostatic capacitance of a sheath (ion sheath) between the wafer 107 and the plasma 102 in contact with the wafer 107.

The metallic earth electrode 131, which is disposed inside an upper portion of the housing 103 and surrounds the plasma 102 in the processing chamber 101, is in contact with the plasma 102 via the thermally sprayed film 105 and a sheath formed on an upper surface thereof. An electrostatic capacitance is also present in the sheath between the earth electrode 131 and the plasma 102. In FIG. 2, these electrostatic capacitances are shown as capacitors of the equivalent circuit having capacitance values of the electrostatic capacitances. Thus, in the state where the plasma 102 is generated, an electrostatic capacitance and the electrical resistance 132 corresponding to materials and shapes of the sheath, the thermally sprayed film 105, and the earth electrode 131 which are disposed between the housing 103 set at the ground potential and the plasma 102 are also formed between the housing 103 and the plasma 102 as elements of the equivalent circuit, and a location having the ground potential and the plasma 102 are coupled.

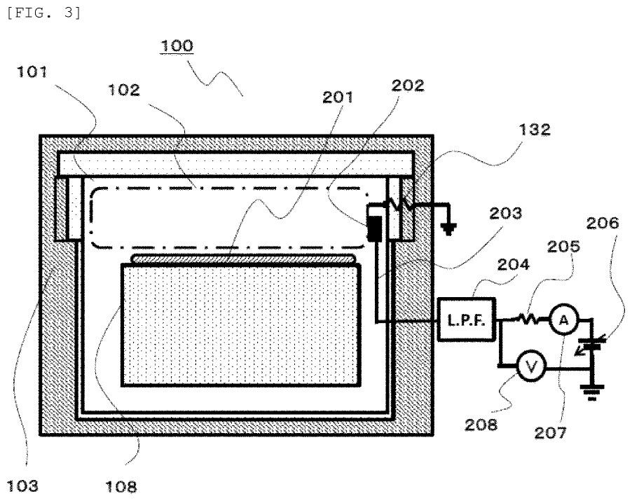

FIG. 3 is a longitudinal sectional view schematically showing an example of a method for detecting the electrical resistance Rc and the withstand voltage Vt of the inner wall of the processing chamber in the plasma processing apparatus according to the embodiment shown in FIG. 1. The plasma processing apparatus 100 shown in FIG. 3 has the same configuration as that in FIG. 1, but is shown by omitting a configuration unnecessary for description. The method for detecting the withstand voltage Vt and the electrical resistance Rc of the inner wall of the processing chamber 101 will be described with reference to FIG. 3.

First, a dielectric plate 201 is placed to cover the upper surface of the dielectric film 122 on the upper surface of the placement electrode 108. Further, a temporary electrode 202 made of a conductor is disposed in the vicinity of the inner wall surface surrounding the space in which the plasma 102 in the processing chamber 101 is generated in advance. The temporary electrode 202 is connected to a coated cable 203, and the coated cable 203 is further pulled out of the housing 103 through a feedthrough (not shown) disposed in the housing 103 and is connected to a variable direct current power source 206 via a low-pass filter 204 and an electrical resistance 205 having a known resistance value (several MΩ in the present example).

Next, under conditions for processing the wafer 107 as a process of manufacturing a semiconductor device, the plasma 102 is generated inside the processing chamber 101, a voltage of direct current power output from the variable direct current power source 206 is gradually increased to apply the voltage to the temporary electrode 202 in contact with the plasma 102, and a value of a current flowing through the coated cable 203 and a potential of the temporary electrode 202 are detected by using an ammeter 207 and an electrometer 208. Since the plasma 102 is a good conductor, the potential of the temporary electrode 202 disposed in the vicinity of the inner wall of the processing chamber 101 can be regarded as indicating a potential of a surface of the inner wall where the plasma 102 is in contact with the inner wall of the processing chamber 101. By using a potential difference and a current of a circuit from the variable direct current power source 206 to the temporary electrode 202, an electrical resistance value Rc of a circuit from a conductive member constituting the housing 103 surrounding the processing chamber 101 to the ground electrode is obtained as a value of the direct current electrical resistance 132, and the direct current electrical resistance 132 of the entire inner wall of the processing chamber 101 in contact with the plasma 102 is interposed between the temporary electrode 202 and the conductive member.

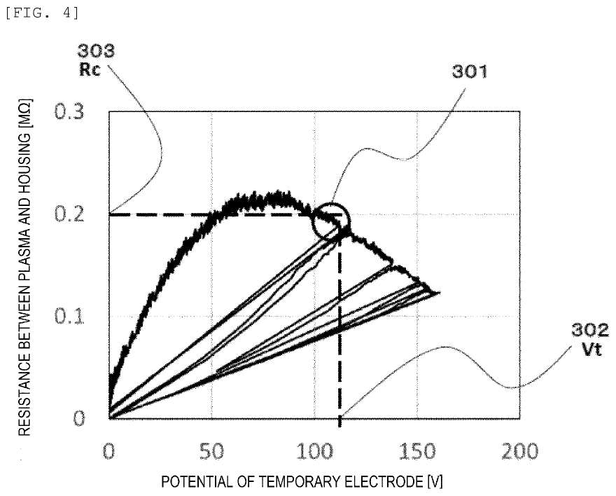

FIG. 4 shows values of the voltage and the electrical resistance obtained in this way. FIG. 4 is a graph showing a change in the resistance value obtained by using the detecting method shown in FIG. 3 with respect to a change in the voltage applied from the variable direct current power source to the temporary electrode.

As shown in FIG. 4, a value 302 of the voltage at a portion 301 where the resistance value changes discontinuously as a value of the direct current voltage applied to the temporary electrode 202 gradually increases is detected as the withstand voltage Vt of the inner wall of the processing chamber 101, and a resistance value 303 corresponding to a value of a voltage equal to or slightly smaller than that at the discontinuous portion 301 is detected as the electrical resistance Rc of the inner wall of the processing chamber 101. Values detected in an example shown in FIG. 4 are the withstand voltage Vt=110 V and the electrical resistance Rc=about 0.2 MΩ. In the present example, the withstand voltage Vt is a withstand voltage at a portion having the lowest voltage among portions where the voltage shows a discontinuous change. The withstand voltage Vt is lower than withstand voltages of the planar thermally sprayed film 105 and the normal anodized film 106, and is considered to indicate a withstand voltage of a weak portion such as a boundary portion or a local corner portion.

Since the withstand voltage value Vt and the resistance value Rc vary depending on a usage history or status of a component constituting the processing chamber 101 of the plasma processing apparatus 100, or a state of a surface of a dielectric component disposed inside the processing chamber 101, it is necessary to detect the withstand voltage value Vt and the resistance value Rc by selecting appropriate conditions. Further, for the value of the withstand voltage Vt and the value of the electrical resistance Rc, a range in which the detected value changes depending on a configuration of dielectric films 105, 106 on the inner wall of the processing chamber 101 having the same configuration may be grasped, and a result thereof may be used instead of detecting the value of the withstand voltage Vt and the value of the electrical resistance Rc for the processing chambers 101 of a plurality of plasma processing apparatuses 100 having the same configuration.

The lift pin lower portion resistance Rps 129 is adjusted in advance to a value within a range, that satisfies the following formula (1) before etching processing of the wafer 107, by using the obtained withstand voltage Vt and the obtained electrical resistance Rc of the inner wall of the processing chamber.

100 MΩ>Rps>1/{(Vt/((δ max−Vt)Rc))−(1/Resc)} (1)

Here, the electrostatic chuck resistance Resc is an electrical resistance value between the wafer 107, and the bipolar inner electrostatic chuck electrode 115 and the bipolar outer electrostatic chuck electrode 116 to which the different polarities are respectively imparted in the present embodiment, and is half of an electrical resistance value between one electrode and the wafer 107.

For example, when electrical resistance values between the wafer 107 and the inner electrostatic chuck electrode 115, and between the wafer 107 and the outer electrostatic chuck electrode 116 are respectively set as Resc+ (reference numeral 120 shown in FIG. 2) and Resc− (reference numeral 121 shown in FIG. 2) on a positive side and a negative side, Resc+/2≈Resc−/2≈Resc, and the dielectric film 122 including the semi-conductive film 119 is sandwiched between the wafer 107, and the inner electrostatic chuck electrode 115 and the outer electrostatic chuck electrode 116. Further, by setting an upper limit of an electrical resistance of the lift pin lower portion resistance Rps 129 in the formula (1) to 100 MΩ, the lower portion of the lift pin 124 or a component at the tip portion of the lift pin holder 126 can be prevented from being charged.

In the present embodiment, the value of the lift pin lower portion resistance Rps 129 is adjusted within a predetermined range, and the average voltage Eesc of the electrostatic chuck electrodes and the lift pin lower portion voltage Eps applied by the variable direct current power source 130 connected to the lift pin lower portion resistance 129 are controlled. Both the electrostatic chuck average voltage Eesc and the lift pin lower portion voltage Eps are controlled so as to follow a potential according to the estimated voltage Vdcs of the self-bias of the wafer.

δ max is called the maximum value of the potential difference, is a maximum value of a difference between an actual self-bias voltage Vdc of the wafer 107 and a control voltage of the following control, and is a value in which a voltage deviation resulting from a time deviation of the following control of the variable direct current power source and an error resulting from voltage control accuracy are also added in addition to a difference between the actual self-bias voltage Vdc and the estimated voltage Vdcs of the self-bias.

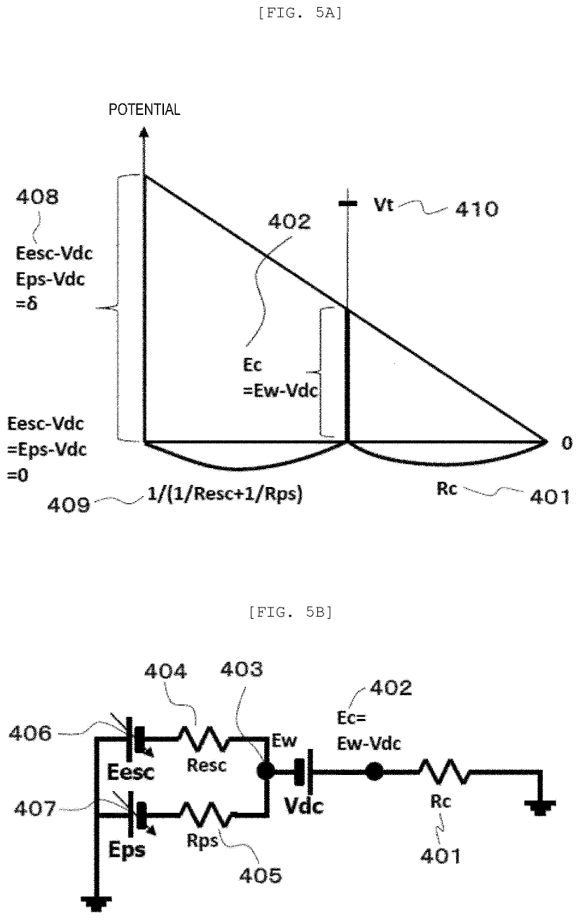

FIGS. 5A and 5B are graphs schematically illustrating an appropriate range of a resistance value of the lower portion of the lift pin of the invention. That is, the above formula (1) will be described with reference to FIGS. 5A and 5B.

FIG. 5B shows an equivalent circuit, including the plasma 102 therein, between the resistance value Rc of the inner wall of the processing chamber 101 and the variable direct current power sources 117, 118, and 130, each having a terminal electrically connected to the ground electrode on one end side, in a state where the plasma 102 is generated in the processing chamber 101 and the first radio frequency power is supplied from the radio frequency power source 112 to the base member 109 to subject the wafer 107 to the etching processing in the plasma processing apparatus 100 of the present embodiment. In particular, FIG. 5B shows a configuration of a circuit for a direct current component of a current when discharge occurs inside the through hole 123 of the lift pin 124, and conduction occurs between the wafer 107 and the lower end portion of the lift pin 124 or between the wafer 107 and a surface of a conductor portion of the lift pin holder 126 connected to the lower portion of the lift pin 124 during a processing period of the wafer 107, and the current flows in these members.

An average potential Ec 402 of an inner surface of the inner wall of the processing chamber 101 corresponding to a portion on a left side of an electrical resistance Rc 401 which represents an electrical resistance value between the inner wall of the processing chamber 101 and the ground electrode is a time-averaged potential of the inner wall surface of the processing chamber 101 facing the plasma 102. An average potential Ew 403 of the wafer 107 differs from the average potential Ec 402 of the inner surface of the inner wall of the processing chamber 101 by the actual self-bias voltage value Vdc of the wafer 107 (Ew−Vdc=Ec). Due to the discharge in the through hole 123, the wafer 107 is electrically connected to the variable direct current power sources 117, 118, and 130 via an electrostatic chuck resistance Resc 404, which is a resistance value of an electrostatic chuck portion including the dielectric film 122, and via a lift pin lower portion resistance Rps 405 passing the lower portion of the lift pin 124 or the conductive member of the lift pin holder 126, respective potentials are set to an electrostatic chuck average voltage Eesc 406 that is a voltage of the inner electrostatic chuck electrode 115 and the outer electrostatic chuck electrode 116, and a lift pin lower portion voltage Eps 407 that is a voltage value of the lower portion of the lift pin 124 or the conductive member of the lift pin holder 126.

When values of the electrostatic chuck average voltage Eesc 406 and the lift pin lower portion voltage Eps 407 are adjusted to the estimated voltage value Vdcs of the self-bias, an average potential Ec of the inner wall surface of the processing chamber 101 facing the plasma 102 is zero if the estimated voltage value Vdcs is the same as the actual self-bias voltage Vdc. When Vdcs is a value different from Vdc, a difference δ 408 between these potentials is linearly distributed between the electrical resistance Rc 401 of the inner wall of the processing chamber 101 and a combined electrical resistance 1/(1/Resc+1/Rps) 409 of the electrostatic chuck resistance Resc and the lift pin lower portion resistance Rps. A value of the average potential Ec 402 of the inner surface of the inner wall of the processing chamber 101 in this case is determined by direct current circuit calculation as in a formula (2).

Ec=δ×Rc/((1/(1/Resc+1/Rps))+Rc) Formula (2)

FIG. 5A is a graph showing a relationship of the formula (2) as a linear line. A condition that the average potential Ec of the inner wall surface of the processing chamber 101 is less than a withstand voltage Vt 410 of the inner wall of the processing chamber 101 is 0<Ec<Vt. A lower limit of the formula (1) is determined based on the formula (2) by using the condition.

Next, the estimated voltage Vdcs of the self-bias of the wafer 107 will be described.

First, as shown in FIG. 1, the plasma processing apparatus 100 of the present embodiment detects a voltage Vpp in the vicinity of the outlet of the matching box 111 based on an output of a voltage detector 110 during the etching processing. The matching box 111 performs adjustment such that an impedance of a path on a radio frequency power source 112 side of the matching box 111 and an impedance Zc of a path from the matching box 111 to the plasma 102 on a processing chamber 101 side match each other. Therefore, a person skilled in the art can obtain the impedance Zc based on a configuration of a circuit from the power source 112 to the matching box 111.

An impedance Zw at the frequency of the first radio frequency power and from the outlet of the matching box 111 to the wafer 107 can also be obtained by measurement or careful calculation of a radio frequency electrical circuit. Therefore, an impedance Zp on a plasma side from the wafer 107 is obtained by Zp=Zc−Zw, and whereby a variation width (amplitude) Vppw in potential generated during one cycle due to the first radio frequency power is expressed by the following formula.

Vppw=(|Zp|/|Zc|)×Vpp

Next, the self-bias voltage Vdc is estimated using the variation width Vppw.

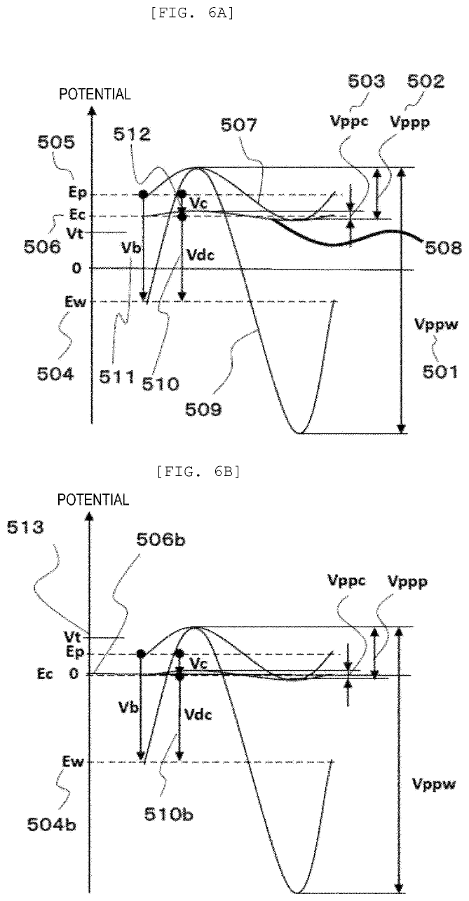

An example of adjustment of an output from a power source of the plasma processing apparatus 100 of the present embodiment will be described with reference to FIGS. 6A and 6B. FIGS. 6A and 6B are graphs showing a change in the output from the power source associated with a change in time during the processing of the wafer performed by the plasma processing apparatus according to the embodiment shown in FIG. 1. In particular, FIGS. 6A and 6B shows the self-bias value during the processing of the wafer 107, and variations in radio frequency potentials of the wafer 107, the plasma 102, and the inner wall surface of the processing chamber 101 over time.

FIG. 6A shows a variation width (amplitude) Vppw 501 in potential generated during one cycle due to the first radio frequency power applied to the wafer 107 during the processing, a potential variation width (amplitude) Vppp 502 of the plasma 102 generated during one cycle, and a potential variation width Vppc 503 of the inner wall surface of the processing chamber 101 generated during one cycle when the electrical resistance value Rc of the inner wall of the processing chamber 101 is high and the average voltage Eesc of the bipolar electrostatic chuck electrodes is 0. Further, direct current voltage values Ew 504, Ep 505, and Ec 506 are shown as average values of the respective potentials.

First, in a state where the first radio frequency power is supplied to the base member 109 and the wafer 107, the potential variation width Vppc 503 of the inner wall surface of the dielectric films 105, 106 on the inner wall of the processing chamber 101 facing the plasma 102 is “an electrostatic capacitance of a member made of a dielectric between the entire inner wall surface of the processing chamber 101 and the housing 103>>an electrostatic capacitance of a medium including the plasma 102 and a plasma sheath between the inner wall surface of the processing chamber 101 and the wafer 107”. Therefore, the potential variation width Vppc 503 of the inner wall surface of the processing chamber 101 due to the radio frequency power is very small as compared with the potential variation width Vppw 501 on the wafer 107 and thus can be ignored.

Further, negatively charged electrons in the plasma 102 are faster than other positive and negative ions due to low mass thereof and thus are quickly escaped from the plasma 102 and incident on a wall, so that an instantaneous potential 507 of the plasma 102 is always higher than an instantaneous potential 508 of the inner wall surface of the processing chamber 101 and an instantaneous potential 509 of the wafer 107. Due to such a physical constraint, based on FIGS. 6A and 6B, a self-bias voltage Vdc 510, which is a potential difference indicating how much an average potential Ew 504 of the upper surface of the wafer 107 is lower than an average potential Ec 506 of the inner wall surface of the processing chamber 101, is approximately expressed by the following formula (3) using the potential variation width Vppp 502 of the plasma 102 and the radio frequency potential variation width Vppw 501 of the wafer.

Vdc=Vb−Vc=Vppw/2−Vppp, Vppp=2Vc (3)

Here, a sheath voltage Vb 511 is a potential difference between an average potential Ep 505 of the plasma 102 and the average potential Ew 504 of the wafer 107, and a sheath voltage Vc 512 is a potential difference between the average potential Ep 505 of the plasma 107 and the average potential Ec 506 of the inner wall surface of the processing chamber 101.

Generally, in processing of a substrate in which plasma generated by capacitive coupling (capacitively coupled plasma) is used, when an area of the substrate to which radio frequency power is supplied is set as Ab, a value of a plasma sheath voltage (potential difference) formed on an upper surface of the substrate is set as Vb 511, an area of an earth (ground) electrode facing the plasma inside a processing chamber is set as Ac, and a value of a plasma sheath voltage (potential difference) formed on the earth electrode is set as Vc 512, a relationship expressed by a formula (Vb/Vc=(Ac/Ab)\hat{ }q, q=1 to 2.5) is generally established. Generally, since an area ratio of Ac/Ab=1.5 to 3 in a plasma processing apparatus, the following formula (4) is obtained when the area ratio is substituted into the above formula.

Vb/Vc=β=1.5 to 15 (4)

Vdc=−(Vppw/2)×(1−2/(β+1)) is obtained based on the formula (3) and the formula (4), and is expressed as the following formula (5) when β=1.5 to 15.

Vdc=−(Vppw/2)×(0.2 to 0.88) (5)

The formula (5) can be expressed as Vdc=−0.27Vppw±0.17Vppw, and in the present embodiment, −0.27×Vppw is regarded as the estimated voltage Vdcs of the self-bias and 0.17×Vppw is regarded as an estimated error. Since the estimated error increases or decreases in proportion to a value of Vppw, a maximum value of the estimated error is a value determined based on Vppwmax which is the maximum. Vppw. That is, a maximum possible potential difference δ max of the potential difference between the actual self-bias voltage Vdc and the control voltage of the electrostatic chuck average voltage Eesc 406 and the lift pin lower portion voltage Eps 407 is expressed by the following formula (6).

0.17×Vppwmax+“error caused by control accuracy” (6)

In the present embodiment, when Vppwmax=1500 V and an error in direct current power source control is ±50 V, δ max=305 V. Further, when the electrostatic chuck resistance Resc=20 MΩ in consideration of a variation caused by a state of a back surface of the wafer 107 or a temperature of the placement electrode 108, the formula (1) is calculated to be 100 MΩ>Rps>0.36 MΩ. Thus, in the present embodiment, Rps=1 MΩ.

FIG. 6B shows radio frequency potential variations Vppw, Vppp, and Vppc, and average potentials Ew, Ep, and Ec of the wafer 107, the plasma 102, and the inner wall surface of the processing chamber 101 when such a set value of Rps is applied. By adjusting the lift pin lower portion voltage Eps and the electrostatic chuck average voltage Eesc, a value of a self-bias voltage Vdc 510b can be set to a value within a predetermined allowable range approximating an average potential Ew 504b of the wafer 107. Further, it can be seen that an average potential Ec 506b of the inner wall surface of the processing chamber 101 is maintained at or below a withstand voltage Vt 513 of the wall.

In the related art, problems arise that unexpected discharge occurs in the through hole 123 of the lift pin 124, conduction 133 shown in FIG. 2 suddenly occurs, and the average potential Ew of the wafer 107 increases. In the present embodiment, a sudden increase in the average potential Ew of the wafer 107 is prevented, and dielectric breakdown of the dielectric films 105, 106 constituting the inner wall surface of the processing chamber 101 and facing the plasma 102 is prevented. Therefore, generation of particles inside the processing chamber 101 is reduced, and a yield, stability, and reproducibility of processing are improved.

Further, since the average voltage Eesc of the electrostatic chuck electrodes is adjusted to be a value within a predetermined allowable range of the self-bias estimated voltage Vdcs of the wafer 107, the average potential Ew of the wafer 107 and the average voltage Eesc of the electrostatic chuck electrodes are approximate values within an allowable range, a potential difference between the average potential Ew of the wafer 107 and a potential of the inner electrostatic chuck electrode 115 is equal to a potential difference between the average potential Ew of the wafer 107 and a potential of the outer electrostatic chuck electrode 116, a difference in the force for attracting the wafer 107 on the upper surface of the dielectric film 122 above these electrodes is reduced as compared with the related art, and a temperature of the wafer 107 can be adjusted accurately. As a result, etching uniformity can be improved.

Instead of estimating the self-bias voltage Vdc as described above, a conversion formula for estimating the self-bias voltage Vdc that varies during the etching processing may be obtained based on actually measured values measured in advance. In this case, a value of a difference when the difference between the conversion formula and the actual self-bias voltage Vdc may be the largest under the processing conditions to be used is used as the maximum value δ max of the potential difference.

In the plasma processing apparatus 100 of the above embodiment, a portion of the metallic housing 103 constituting the inner wall of the processing chamber 101 and including a lower portion of the processing chamber 101 can be almost entirely covered with a thermally sprayed film, and an anodized coating can be used on a surface of a portion, which faces a region where a density of the plasma 102 is low and is made of aluminum or an alloy thereof. According to a study performed by the inventors, in the present example, the electrical resistance between the inner wall surface of the processing chamber 101 and the ground electrode is Rc=2 MΩ in an initial stage immediately after use of the plasma processing apparatus 100 is started, but decreases to Rc=60 kΩ at a time point after plasma processing is performed for a long period of time (100 hours in the present example). The withstand voltage Vt is 110 V.

Further, the wafer 107 in the present example is made of silicon, and the electrostatic chuck resistance Resc between the bipolar electrostatic chuck electrodes and the wafer 107 is 2.5 MΩ. The maximum Vppw to be used is 1000 V.

When the appropriate lift pin lower portion resistance Rps is obtained using the formula (1) in the above embodiment, the lift pin lower portion resistance Rps is 100 MΩ>Rps>3.2 MΩ at the time of initial use and long-term use and is 100 MΩ>Rps>42 kΩ at the time of processing the wafer 107 in the processing chamber 101 for 100 hours, and therefore the lift pin lower portion resistance Rps is set to 5 MΩ.

In the present example, when the lift pin lower portion resistance Rps is set to 5 MΩ, the lift pin lower portion voltage Eps and the electrostatic chuck average voltage Eesc are not controlled and kept at 0 V, and the plasma processing apparatus is used under a condition of Vppw of 1000 V, the self-bias voltage Vdc of about 270 V is generated. In this case, in a state of the inner wall surface of the processing chamber 101 at the time of initial use and long-term use, the average potential Ec of the inner wall surface of the processing chamber 101 is predicted to be a relatively high value such as 147 V based on the formula (2) and is higher than the withstand voltage Vt, and therefore unexpected discharge or conduction may occur between the wafer 107 and the lower portion of the lift pin 124 or a conductive member on the upper surface of the lift pin holder 126 and unexpected discharge (abnormal discharge) may occur inside the processing chamber 101.

Therefore, the lift pin lower portion voltage Eps and the electrostatic chuck average voltage Eesc need to be appropriately adjusted. However, since the electrical resistance Rc between the processing chamber 101 and the ground electrode decreases after the processing is performed for a long period of time as described above, the average potential Ec of the inner wall surface of the processing chamber 101 is predicted to be about 9 V, and a possibility of occurrence of the abnormal discharge is low. However, in a case where the lift pin lower portion resistance Rps is lower than the range determined in the present example, the average potential Ec of the inner wall surface of the processing chamber 101 may increase by an amount corresponding to the self-bias voltage Vdc and may abnormally discharge in a place where the withstand voltage of the inner wall of the processing chamber 101 is low when unexpected conduction occurs in the through hole 123, and the particles may be generated on the wafer 107.

In the above embodiment, the Johnsen-Rahbek electrostatic chuck is used, but a Coulomb electrostatic chuck may be used instead of the Johnsen-Rahbek electrostatic chuck. In a case of the Coulomb electrostatic chuck, the formula (1) becomes the following formula (7) since Resc>>Rc.

100 MΩ>Rps>1/{(Vt/((δ max−Vt)Rc))} (7)

In addition, when it is assumed that the conditions are the same as those in the first embodiment, the conditions are that the electrical resistance Rc of the inner wall of the processing chamber=0.2 MΩ, the withstand voltage Vt=110 V, the maximum value Vppwmax of Vppw=1500 V, and the error in direct current power source control is 50 V.

A value of the appropriate lift pin lower portion resistance Rps is 100 MΩ>Rps>0.355 MΩ based on the formula (7), which is equivalent to that in the first embodiment. Similarly to the above embodiment, Rps=1 MΩ may be also set in a case of the present example.

Further, the lift pin lower portion voltage Eps and the electrostatic chuck average voltage Eesc change depending on a magnitude of the first radio frequency power supplied to the wafer 107, where Vdcs=0.27×Vppw.

In the case of the present example, the average voltage Eesc of the electrostatic chuck electrodes does not affect the average potential Ew of the wafer 107 and the average potential Ep of the plasma 102. If the lift pin lower portion resistance Rps is set as described above and the lift pin lower portion voltage Eps is controlled, the increase in the average potential Ew of the wafer 102 can be prevented even when the unexpected conduction occurs inside the through hole 123 in which the lift pin 124 is stored. However, in order to eliminate a variation in an attraction force, it is preferable to adjust the electrostatic chuck average voltage Eesc so as to match the self-bias voltage Vdc. When uniformity of the attraction force in an in-plane direction of the wafer 107 is improved, a variation in temperature in the in-plane direction of the wafer 107 is reduced, and the uniformity and the stability of the processing such as the etching processing are improved.

When the radio frequency power is supplied to the base member 109 by performing so-called time modulation in which the supply of the first radio frequency power is periodically turned on or off at a frequency in a band of several Hz to several tens of Hz or higher during the processing of the wafer 107, a time-averaged value of Vdcs may be obtained by multiplying the estimated voltage Vdcs of the self-bias in a period during which the first radio frequency power is turned on by a ratio of an on time to the entire period of the processing, and the lift pin lower portion voltage Eps and the average voltage Eesc of the electrostatic chuck electrodes may be adjusted based on the averaged value of Vdcs. A reason thereof is that since orientation polarization or ionic polarization of the dielectric film on the inner wall of the processing chamber 101 has a time constant slower than that of a frequency at which a time-modulated wafer bias is turned on or off, the potential applied to the inner wall of the processing chamber is averaged by an absorption current of the polarization.

The invention is not limited to the above embodiment, and includes various modifications. The embodiment is described in detail for easy understanding of the invention, and the invention is not necessarily limited to those the same as all the use conditions described above. A part of a configuration of one embodiment may be replaced with a configuration of another embodiment. Further, the invention is not limited to the control voltage, the set resistance value, the withstand voltage, and the electrical resistance of the wall of the processing chamber in an example given in the embodiment.

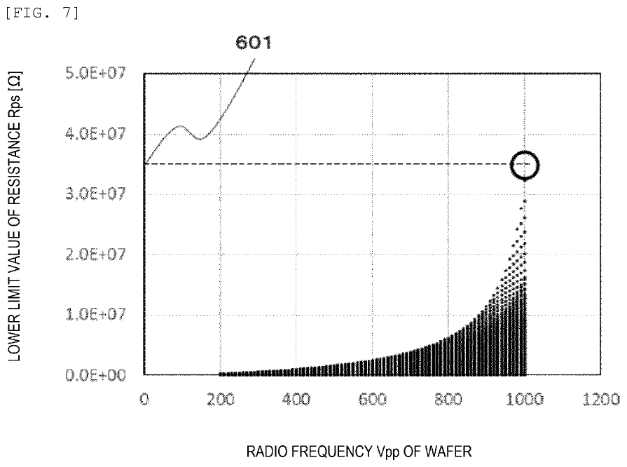

FIG. 7 shows a graph in which a lower limit value of a required lift pin lower portion resistance Rps is obtained based on the formulas (1) and (6) when a process with Vppw of the wafer up to 1000 V is used in a case where the electrical resistance of the inner wall of the processing chamber is in a range of Rc=50 kΩ to 1.2 MΩ, the control accuracy of the direct current power source is in a range of 10 V to 50 V, the electrostatic chuck resistance is in a range of Resc=2.5 MΩ to 3 GΩ, and the withstand voltage of the wall of the processing chamber is in a range of Vt=V to 125 V.

Respective points in FIG. 7 are cases of combinations of various parameters. The electrical resistance Rc of the inner wall of the processing chamber is within a range assumed when the inner wall of the processing chamber is the thermally sprayed film. According to calculation, when the electrical resistance Rc of the inner wall of the processing chamber is set to 1.2 MΩ or higher, in some combinations of the parameters, the average potential Ec of the inner surface of the inner wall of the processing chamber may exceed the withstand voltage Vt during the etching processing regardless of setting of the lift pin lower portion resistance. Therefore, the electrical resistance Rc of the inner wall of the processing chamber needs to be set to 1.2 MΩ or lower. The electrical resistance Rc is limited by a relative magnitude with respect to the J-R electrostatic chuck resistance Resc.

The electrostatic chuck resistance Resc is within a range assumed in a range from a J-R type to a Coulomb type. The withstand voltage Vt of the inner wall of the processing chamber is within a range which is obtained based on results of measuring the withstand voltage Vt in several processes in an apparatus in which the thermally sprayed film is mainly used and anodized film made of aluminum is partially used.

The control accuracy of the direct current power source is generally within a possible range. In a case of the apparatus corresponding to the above range, when the lift pin lower portion resistance Rps is set to a resistance value 601 of 35 MΩ or higher, effects of the present example can be achieved in a process in which Vppw is 1000 V or lower. More preferably, by setting the lift pin lower portion resistance Rps to 100 MΩ>Rps>35 MΩ, a time constant during which electric charges at the lower portion of the lift pin 124 escape can be shortened, and the lower portion of the lift pin 124 can also be prevented from being charged after occurrence of the conduction.

### INDUSTRIAL APPLICABILITY

The plasma processing apparatus of the invention can be used for a semiconductor wafer processing apparatus to be used in a process of manufacturing a semiconductor device.

### REFERENCE SIGN LIST

100: plasma processing apparatus
101: processing chamber
102: plasma
103: housing
104: top plate
105: thermally sprayed film
106: anodized film
107: wafer
108: placement electrode
109: base member
110: voltage detector
111: matching box
112: radio frequency power source
124: lift pin
125: boss
126: lift pin holder
127: beam portion
128: drive mechanism
129: lift pin lower portion resistance
130: variable direct current power source
131: earth electrode
132: electrical resistance
133: conduction
136: bellows

1. A plasma processing apparatus, comprising:
a processing chamber which is disposed inside a vacuum container and inside which plasma is to be generated;
a wafer stage which is disposed inside the processing chamber and on which a processing target wafer is placed;
an electrostatic chuck including a film-shaped electrostatic attraction electrode which is disposed in a dielectric film covering an upper surface of the wafer stage and which electrostatically attracts the wafer placed on the dielectric film;
a radio frequency electrode which is disposed inside the wafer stage and to which radio frequency power is supplied during processing of the wafer; and
a lift pin which is disposed inside the wafer stage and which moves the wafer up and down by movement thereof in an up and down direction, a lower portion of the lift pin being connected to a member made of a conductor, wherein
when an electrical resistance value between the electrostatic attraction electrode and the wafer is set as Resc, an electrical resistance between the plasma and a ground electrode with an inner wall surface of the processing chamber interposed between the plasma and the ground electrode is set as Rc, a withstand voltage between the plasma and the vacuum container constituting the processing chamber is set as Vt, and a predicted maximum value of a difference between a self-bias voltage Vdc actually generated in the wafer during the processing of the wafer and a predicted value Vdcs thereof is set as δ max, a resistance value Rps between a direct current power source and the lower portion of the lift pin electrically connected to the direct current power source is set to a range of 100 MΩ>Rps>1/{(Vt/((δ max−Vt)×Rc))−(1/Resc)}, and
when an average value of a potential of the electrostatic attraction electrode is set as Eesc, a voltage value Eps of the lower portion of the lift pin and the average value Eesc of the potential of the electrostatic attraction electrode are adjusted during the processing of the wafer so as to match the predicted value Vdcs of the self-bias voltage of the wafer.

2. The plasma processing apparatus according to claim 1, wherein
a ratio of an area of an earth electrode, which is disposed inside the processing chamber and faces the plasma, to an area of the wafer is 1.5 or more to 3 or less, and when an amplitude value of a potential formed on the wafer due to the radio frequency power is set as Vppw, the predicted value Vdcs of the self-bias voltage of the wafer is set to −0.27×Vppw±δ max and max is set to a maximum value Vppwmax×0.17±50, Vppwmax being a maximum value of the Vppw.

3. The plasma processing apparatus according to claim 1, wherein
the predicted value Vdcs of the self-bias voltage is determined in advance as a function of Vpp.

4. The plasma processing apparatus according to claim 1, wherein
the electrostatic chuck is a bipolar electrostatic chuck.

5. The plasma processing apparatus according to claim 1, wherein
the inner wall surface of the processing chamber is configured with a dielectric member including a coating.

6. The plasma processing apparatus according to claim 5, wherein
the dielectric member includes an anodized coating, the electrical resistance Rc between the plasma and the ground electrode with the inner wall surface of the processing chamber interposed between the plasma and the ground electrode is 1.2 MΩ or lower, the amplitude value Vppw of the potential of the radio frequency power is 1000 V or lower, and the resistance value Rps is adjusted to 100 MΩ>Rps>35 MΩ.
